(19) United States
(12) Patent Application Publication
(10) Pub. No.: US 2007/0029655 A1
(43) Pub. Date: Feb. 8, 2007

(54) Jig structure for manufacturin a stacked memory card

(76) Inventors: Hong Tsu Chang, Hsinchu Hsien (TW); Dennis Pai, Hsinchu Hsien (TW); Frank Lung, Hsinchu Hsien (TW); Jay Lin, Hsinchu Hsien (TW); Men San Lung, Hsinchu Hsien (TW)

Correspondence Address: PRO-TECHTOR INTERNATIONAL SERVICES, 20775 NORADA CT., SARATOGA, CA, 95070, US

(21) Appl. No.: 11/195,218

(22) Filed: Aug. 2, 2005

(51) Int. Cl. H01L 23/02

(52) U.S. Cl. 257/679

(57) ABSTRACT

A jig structure for manufacturing a stacked memory card, wherein the stacked memory card has a substrate forming with a package area and at least a electrical element, the jig structure is formed with a penetrated slot corresponding to the mounted area of the substrate and at least a protection cover corresponding to the electrical element.

### BACKGROUND OF THE INVENTION

1. Field of the Invention

The invention relates to a jig structure for manufacturing a stacked memory card, and particular to a memory card with B-stage glue for forming a stacked memory card, the reliability of the stacked memory card may be promoted.

2. Description of the Related Art

A conventional stacked memory card includes upper chip and lower chip, the upper chip is adhered on the lower chip by way of non-conductive glue, and the lower chip is adhered on the substrate by the non-conductor glue, while the quality of the non-conductor glue is property, the lower chip is bumpy, so that the stacked memory card is bumpy.

### SUMMARY OF THE INVENTION

An objective of the invention is to provide a jig structure for manufacturing a stacked memory card capable of increasing the reliability of the stacked memory card.

To achieve the above-mentioned object, wherein the stacked memory card has a substrate forming with a package area and at least a electrical element, the jig structure is formed with a penetrated slot corresponding to the mounted area of the substrate and at least a protection cover corresponding to the electrical element.

### BRIEF DESCRIPTION OF THE DRAWINGS

FIG. 1 is a cross-sectional view schematic illustration showing a stacked memory card.

FIG. 2 is an illustration view showing a substrate of a stacked memory card of the present invention.

FIG. 3 is a cross-sectional view schematic illustration showing a jig structure for manufacturing a stacked memory card of the present invention.

FIG. 4 is an illustration view showing a jig structure for manufacturing a stacked memory card of the present invention.

### DETAILED DESCRIPTION OF THE INVENTION

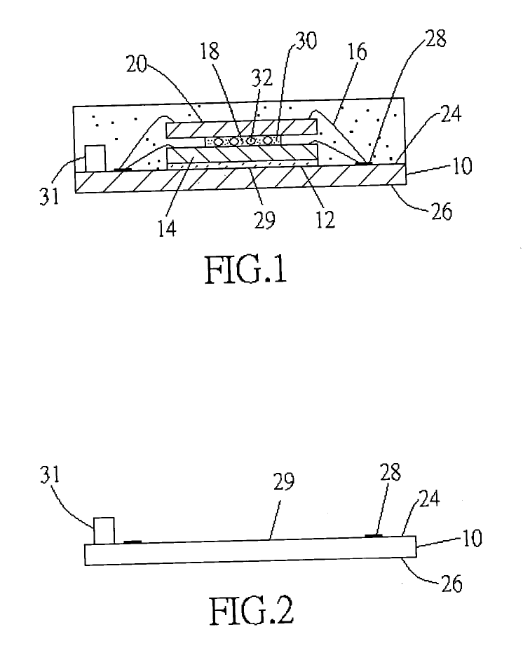

Please refer to FIG. 1, and FIG. 2, a jig structure for manufacturing a stacked memory card of the present invention includes a substrate, B-stage glue 12, lower chip 14, wires 16, an adhesive element 18, an upper chip 20, and a compound resin 22.

The substrate 10 has an upper surface 24 formed with a plurality of first electrodes 28, mounted region 29, and electrical element 31,and a lower surface 26.

The B-stage glue 12 is coated on the upper surface 24 of the substrate 10 by printing matter.

The lower chip 14 is arranged on the upper surface 24 of the substrate 10, and is located on the B-stage glue 12.

The wires 16 are electrically connected the lower chip 14 to the first electrode 18 of the substrate 10.

The adhesive element 16 coated on the lower chip 14 includes an adhesive agent 30 and filling elements 32, in the embodiment, the filling elements 32 are ball sharp.

The upper chip 20 is adhered on the lower chip 14 by adhesive element 16, and is spaced with the lower chip 14 through the filling element 32, then is electrically connected to the first electrode 28 of the substrate 10 by wires 16.

The compound resin 22 is encapsulated on the upper chip 20, lower chip 14, and wires 16.

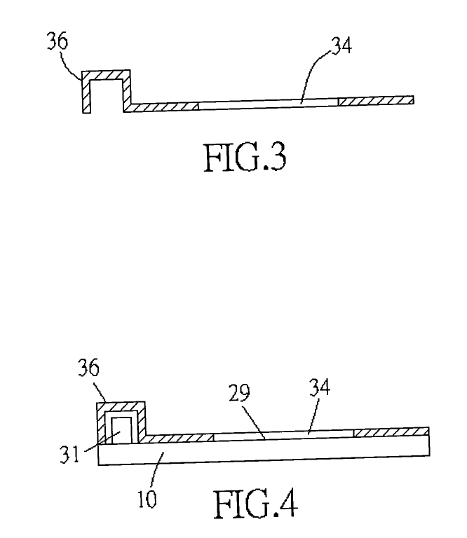

Please refer to FIG. 3, and FIG. 4, a jig structure for manufacturing stacked memory card includes a penetrated slot 34 corresponding to the mounted region 29 of the substrate 10, and a protect cover 36 corresponding to the electrically element 31. Therefore, the B-stage glue 12 is coated on the upper surface 24 of the substrate 10 through the penetrated slot 34, and the electrical element 31 is covered by the protect cover 36.

While the invention has been described by the way of an example and in terms of a preferred embodiment, it is to be understood that the invention is not limited to the disclosed embodiment. On the contrary, it is intended to cover various modifications. Therefore, the scope of the appended claims should be accorded the broadest interpretation so as to encompass all such modifications.

What is claimed is:

1. A jig structure for manufacturing a stacked memory card, wherein the stacked memory card has a substrate forming with a package area and at least a electrical element, the jig structure is formed with a penetrated slot corresponding to the mounted area of the substrate and at least a protection cover corresponding to the electrical element.
